(19) United States
(12) Patent Application Publication
(10) Pub. No.: US 2012/0132982 A1
(43) Pub. Date: May 31, 2012

(54) Non-Volatile Memory Devices

(75) Inventors: Chang-Hyun LEE, Suwon-si (KR); Byung-Kyu CHO, Seoul (KR); Jang-Hyun YOU, Seoul (KR); Albert FAYRUSHIN, Suwon-si (KR)

(73) Assignee: Samsung Electronics Co., Ltd.

(21) Appl. No.: 13/282,575

(22) Filed: Oct. 27, 2011

(30) Foreign Application Priority Data
Nov. 29, 2010 (KR) 10-2010-0119297

(51) Int. Cl. H01L 29/788

(52) U.S. Cl. 257/321; 257/E29.3

(57) ABSTRACT

A non-volatile memory device includes gate structures, an insulation layer pattern, and an isolation structure. Multiple gate structures being spaced apart from each other in a first direction are formed on a substrate. Ones of the gate structures extend in a second direction that is substantially perpendicular to the first direction. The substrate includes active regions and field regions alternately and repeatedly formed in the second direction. The insulation layer pattern is formed between the gate structures and has a second air gap therein. Each of the isolation structures extending in the first direction and having a first air gap between the gate structures, the insulation layer pattern, and the isolation structure is formed on the substrate in each field region.

### CROSS-REFERENCE TO RELATED APPLICATIONS

This application claims priority under 35 USC §119 to Korean Patent Application No. 2010-0119297, filed on Nov. 29, 2010 in the Korean Intellectual Property Office (KIPO), the contents of which are herein incorporated by reference in their entirety.

### BACKGROUND

As non-volatile memory devices have become more highly integrated, the parasitic capacitance between word lines may be increased and the channel coupling between active regions may occur. In order to solve the above problems, a method of forming an air gap between the word lines has been developed.

### SUMMARY

Example embodiments provide non-volatile memory devices having an air gap for reducing a parasitic capacitance and a channel coupling effectively.

Example embodiments provide methods of manufacturing the non-volatile memory device.

According to some embodiments, there is provided a non-volatile memory device. The non-volatile memory device includes gate structures, an insulation layer pattern and an isolation structure. A substrate includes active regions and field regions alternately and repeatedly formed in a second direction perpendicular to a first direction. Multiple gate structures on the substrate are spaced apart from each other in the first direction. Each of the gate structures extends in the second direction. The insulation layer pattern having a second air gap therein is formed between the gate structures. The isolation structures on the substrate in each field region extend in the first direction and have a first air gap between the gate structures, the insulation layer pattern, and the isolation structure.

In some embodiments, the active regions of the substrate may protrude from the field regions of the substrate.

Some embodiments provide that the isolation structure may include a liner and a filling layer sequentially stacked on the substrate in each field regions.

In some embodiments, the liner may surround sidewalls of the protruded active regions and have a cup-shape of which a central portion is empty, and the filling layer may partially fill the empty central portion of the liner.

Some embodiments provide that the first air gap may be defined by a top surface of the filling layer, a sidewall of the liner, a bottom surface of the gate structures, and a bottom surface of the insulation layer pattern.

In some embodiments, each of the gate structures may include a tunnel insulation layer pattern, a floating gate electrode, a dielectric layer pattern, and a control gate electrode sequentially stacked on the substrate.

In some embodiments, the tunnel insulation layer pattern and the floating gate electrode may be formed only in the active regions and the dielectric layer pattern, and the control gate electrode may extend in the second direction in both of the active regions and the field regions.

Some embodiments provide that the first air gap may be defined by the isolation structure, a bottom surface of the dielectric layer pattern, and a bottom surface of the insulation layer pattern.

In some embodiments, the first air gap may have, a bottom surface lower than that of the tunnel insulation layer pattern and a top surface higher than a bottom surface of the floating gate electrode.

In some embodiments, the first air gap and second air gaps may be in fluid communication with each other.

In some embodiments, the insulation layer pattern may be also formed on a top surface of the isolation structure and on bottom surfaces of the gate structures, so that the first air gap may be formed in the insulation layer pattern.

Some embodiments provide that the first air gap and the second air gap may be in fluid communication with each other.

In some embodiments, the non-volatile memory device includes spacers on sidewalls of the gate structures, and the insulation layer pattern may be formed between the spacers.

Some embodiments provide that the first air gap may extend in the first direction, and the second air gap may extend in the second direction.

According to some embodiments, there are provided methods of manufacturing a non-volatile memory device. In such methods, multiple gate structures are formed on a substrate. The substrate is divided into active regions and field regions alternately and repeatedly formed in a second direction. Each of the active regions and the field regions extends in a first direction substantially perpendicular to the second direction. The gate structures spaced apart from each other in the first direction. Each of the gate structures extends in the second direction. An insulation layer pattern is formed between the gate structures. The insulation layer pattern has a second air gap therein. An isolation structure is formed on the substrate in each field region. The isolation structures extend in the first direction and have a first air gap between the gate structures, the second insulation layer pattern, and the isolation structure.

According to some embodiments, there are provided methods of manufacturing a non-volatile memory device. In such methods, a tunnel insulation layer and a floating gate electrode layer are sequentially formed on a substrate. A preliminary tunnel insulation layer pattern, a preliminary floating gate electrode, and a trench are formed by respectively etching the tunnel insulation layer, the floating gate electrode layer, and an upper portion of the substrate. A first insulation layer pattern is formed to partially fill the trench. A dielectric layer and a control gate electrode layer are formed on the preliminary floating gate electrode and the first insulation layer pattern. The control gate electrode layer, the dielectric layer, the preliminary floating gate electrode, and the preliminary tunnel dielectric layer pattern are patterned to form gate structures including a control gate electrode, a dielectric layer pattern, a floating gate electrode, and a tunnel dielectric layer pattern and to partially expose the first insulation layer structure pattern. A first air gap is formed by removing the exposed the first insulation layer structure pattern. A second insulation layer pattern is formed between the gate structures, the second insulation layer pattern having a second air gap.

Some embodiments provide that the first insulation layer structure pattern may partially fill a gap formed between the preliminary tunnel dielectric layer pattern and the preliminary floating gate electrode.

In some embodiments, the first insulation layer structure pattern may include a liner, a first filling layer, and a second filling layer. The liner may cover an inside of the trench, a sidewall of the preliminary tunnel insulation layer pattern, and a portion of a sidewall of the preliminary floating gate electrode. The liner may have an empty cup-shape. The first filling layer on the liner partially may fill the liner. The second filling layer on the first filling layer may fill a remaining portion of the liner.

Some embodiments provide that forming a first air gap by partially removing the first insulation layer structure pattern may include removing the second filling layer.

In some embodiments, the first air gap and the second air gap may be connected to each other.

According to some embodiments, a non-volatile memory device may have a relatively low channel coupling by a first air gap between active regions. Some embodiments provide that the non-volatile memory device may have a relatively low parasitic capacitance by a second air gap between word lines. Accordingly, the non-volatile memory device may have good electrical characteristics.

It is noted that aspects of the invention described with respect to one embodiment, may be incorporated in a different embodiment although not specifically described relative thereto. That is, all embodiments and/or features of any embodiment can be combined in any way and/or combination. These and other objects and/or aspects of the present invention are explained in detail in the specification set forth below.

### BRIEF DESCRIPTION OF THE DRAWINGS

The accompanying figures are included to provide a further understanding of the present inventive concept, and are incorporated in and constitute a part of this specification. Example embodiments will be more clearly understood from the following detailed description taken in conjunction with the accompanying drawings. FIGS. 1 to 16 represent non-limiting, example embodiments as described herein.

FIG. 1 is a cross-sectional view illustrating a non-volatile memory device in accordance with some embodiments disclosed herein.

FIG. 2 is a perspective view illustrating the non-volatile memory device in

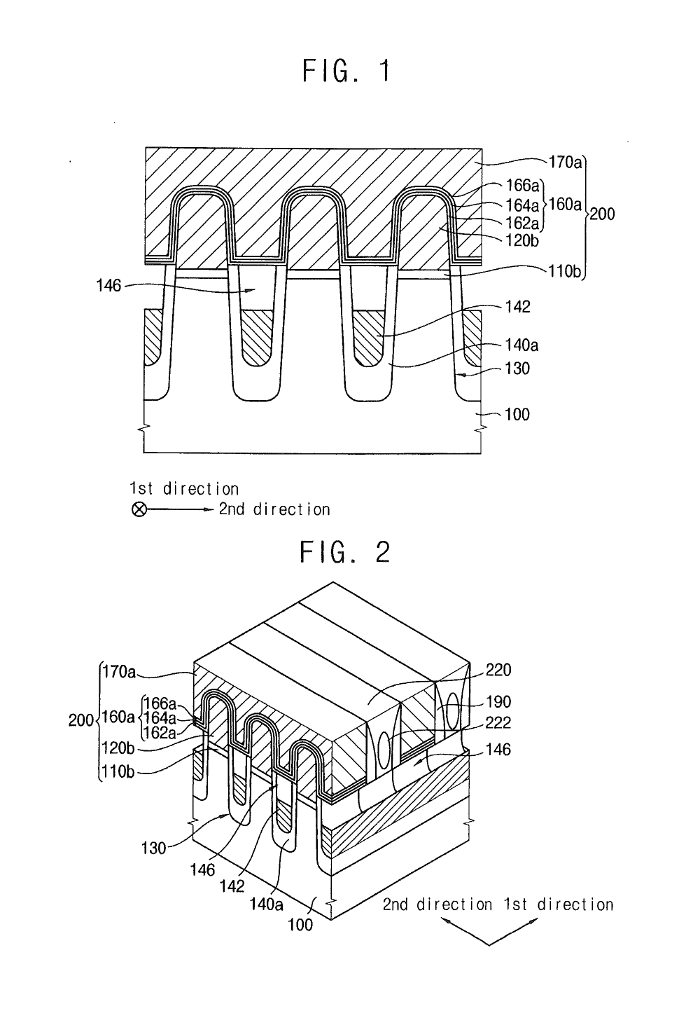

FIG. 1.

FIG. 3 is a plan view illustrating the non-volatile memory device in FIG. 1.

FIGS. 4 to 8 are cross-sectional views illustrating methods of manufacturing the non-volatile memory device in FIGS. 1 to 3 in accordance with some embodiments disclosed herein.

FIGS. 9 to 12 are perspective views illustrating methods of manufacturing the non-volatile memory device in FIGS. 1 to 3 in accordance with some embodiments disclosed herein.

FIG. 13 is a perspective view illustrating a non-volatile memory device in accordance with some embodiments disclosed herein.

FIG. 14 is a cross-sectional view illustrating the non-volatile memory device in FIG. 13.

FIG. 15 is a plan view illustrating a non-volatile memory device in accordance with some embodiments disclosed herein.

FIG. 16 a perspective view illustrating a non-volatile memory device in accordance with some embodiments disclosed herein.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

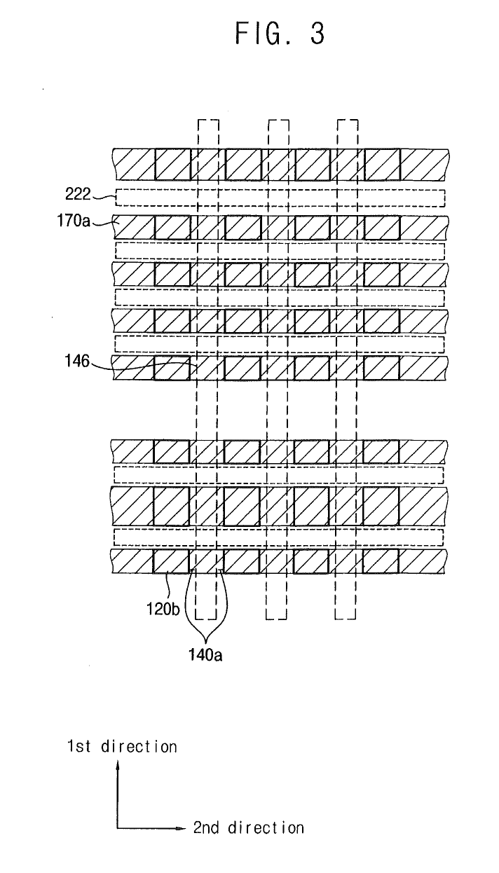

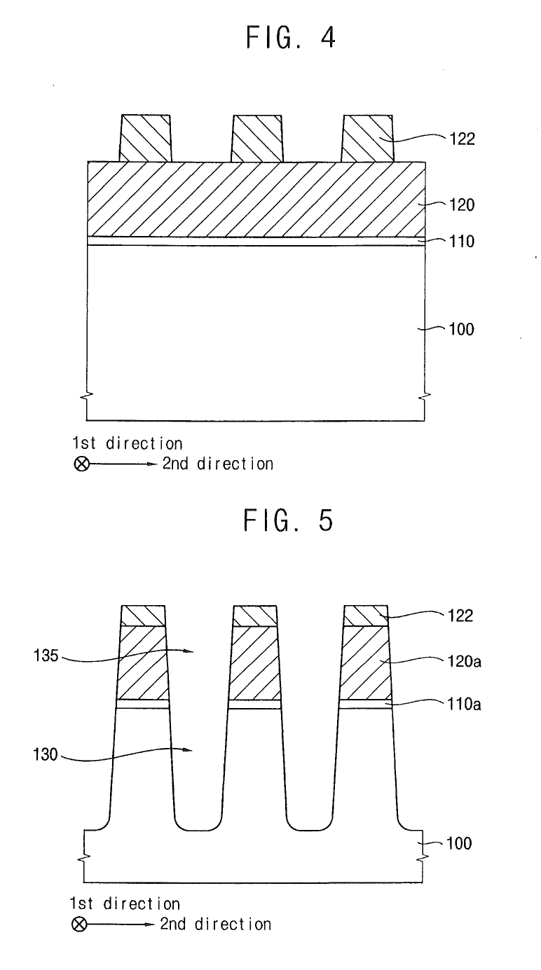

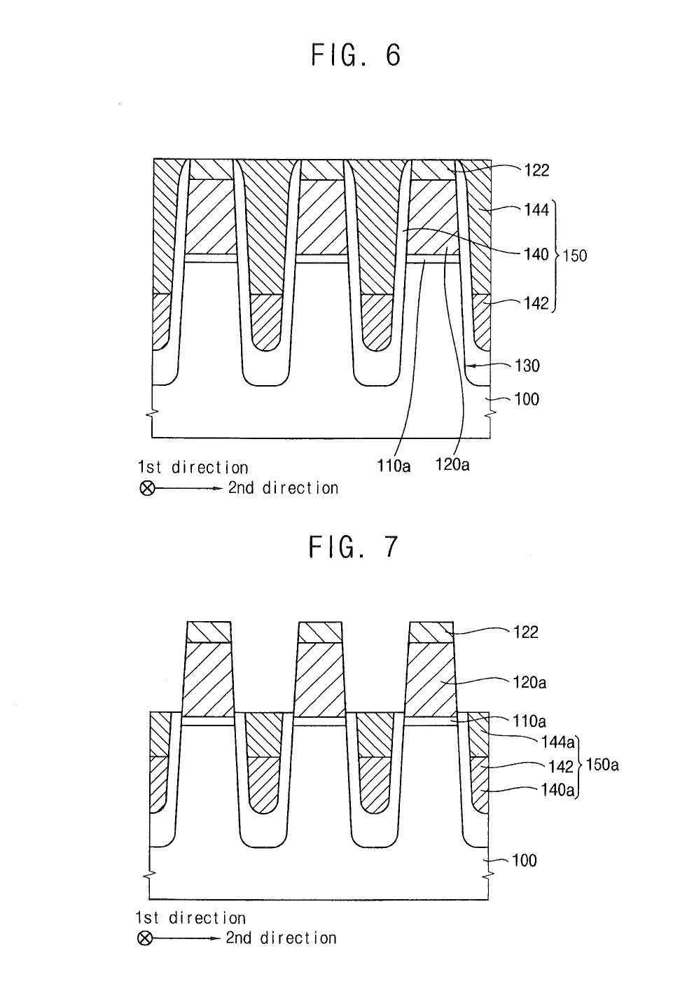

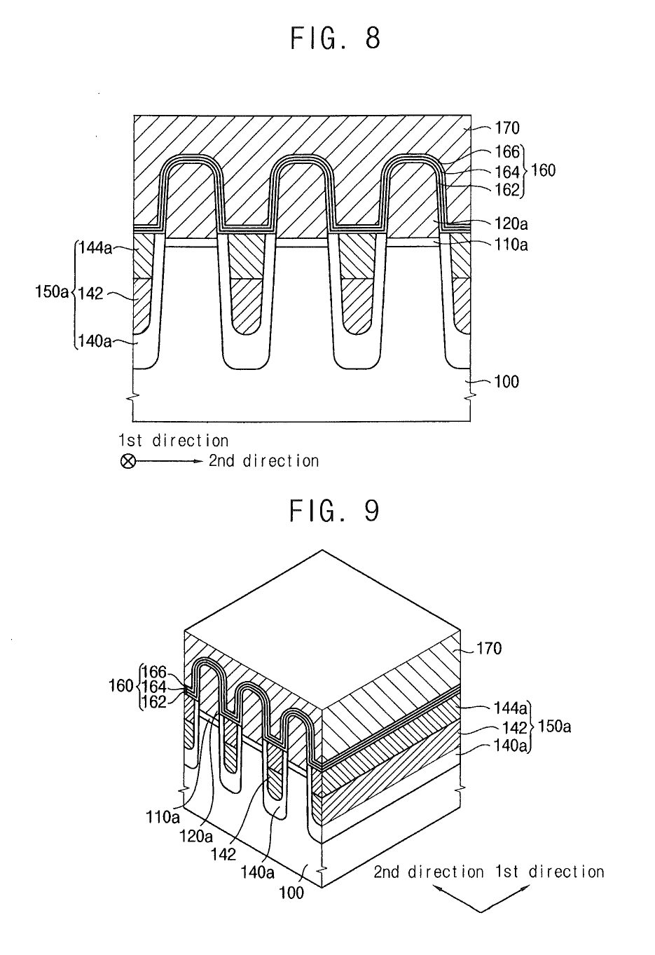

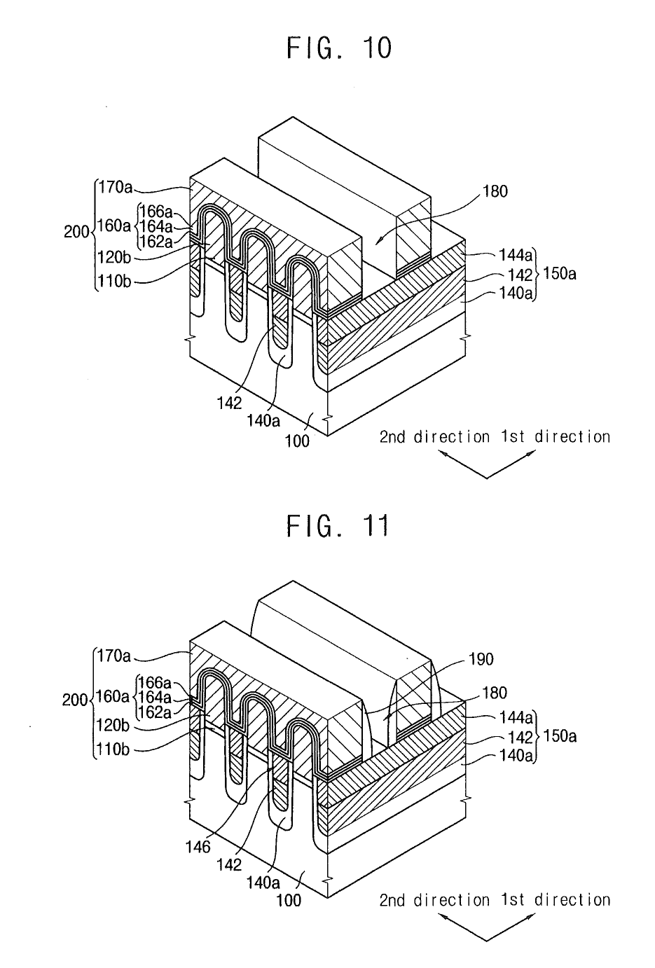

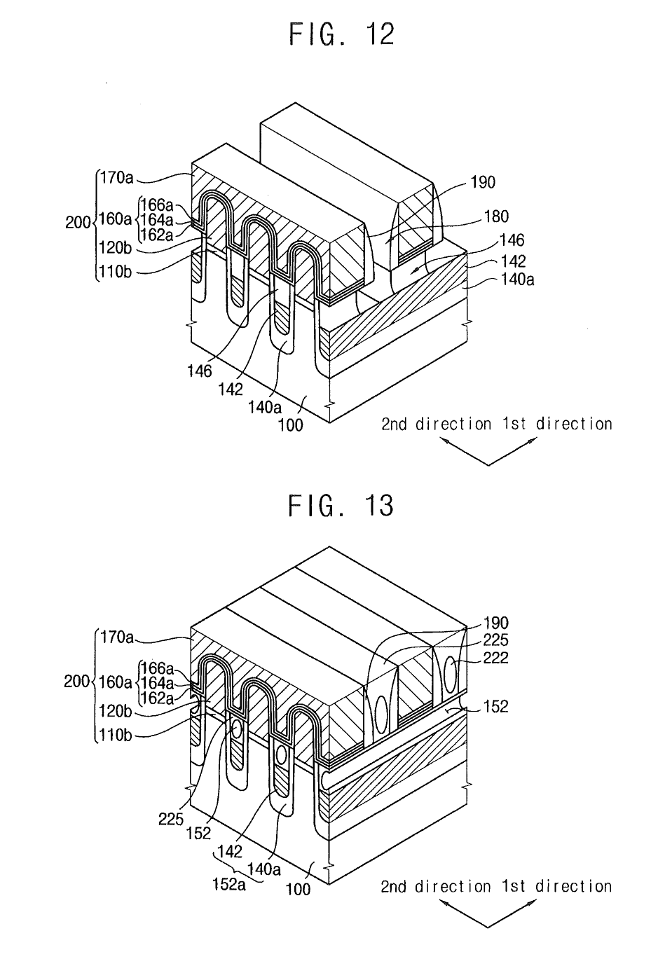

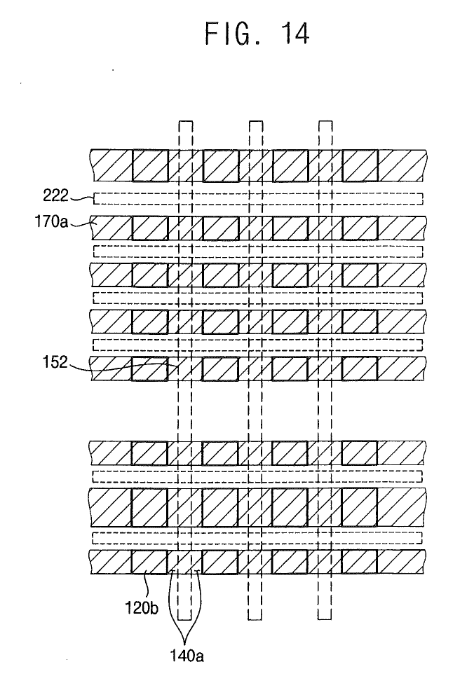

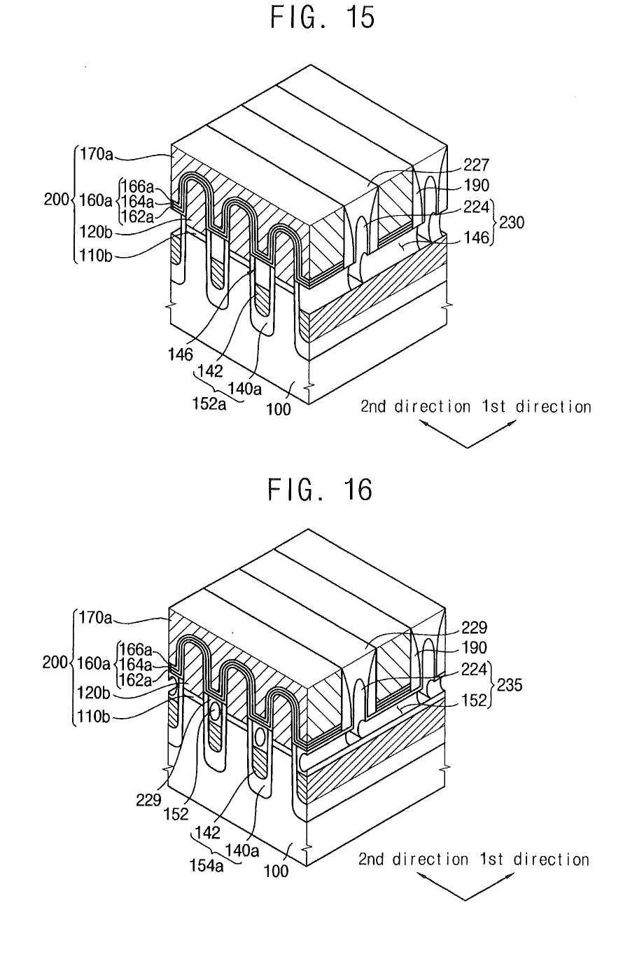

FIG. 1 is a cross-sectional view illustrating a non-volatile memory device in accordance with some embodiments, FIG. 2 is a perspective view illustrating the non-volatile memory device in FIG. 1, and FIG. 3 is a plan view illustrating the non-volatile memory device in FIG. 1.

Referring to FIGS. 1 to 3, the non-volatile memory device may include a plurality of gate structures 200 spaced apart from each other on a substrate 100 in a first direction, each of which may extend in a second direction substantially perpendicular to the first direction, a second insulation layer pattern 220 having a second air gap 222 therein between the gate structures 200, and isolation structures each of which may extend in the first direction and have a first air gap 146 between the gate structures 200 and the isolation structure. As used herein, the term “air gap” may refer to a void in a structure that includes one or more solid components and is not limited to a particular gaseous composition therein. The non-volatile memory device may further include spacers 190 each of which may be formed on a portion of a sidewall of each gate structure 200.

The substrate 100 may be divided into a field region in which the isolation structures may be formed, and an active region in which the isolation structures may not be formed. Each isolation structure may be formed in a trench 130 extending in the first direction on the substrate 100, and thus the active region may also extend in the first direction. The active region of the substrate 100 may protrude from the field region of the substrate 100. The active region and the field region may be formed alternately and repeatedly in the second direction.

Each gate structure 200 may include a tunnel insulation layer pattern 110b, a floating gate electrode 120b, a dielectric layer pattern 160a and a control gate electrode 170a sequentially stacked on the substrate 100 and the isolation structures.

The tunnel insulation layer patterns 110b may have an isolated shape from each other in the active regions. That is, a plurality of tunnel insulation layer patterns 110b may be formed in the first direction in each active region, and further a plurality of tunnel insulation layer patterns 110b may be formed in the second direction in the active regions. The tunnel insulation layer patterns 110b may include silicon oxide, silicon oxynitride, and/or silicon oxide doped with impurities.

The floating gate electrodes 120b may be formed on the tunnel insulation layer patterns 110b. Thus, the floating gate electrodes 120b may also have an isolated shape from each other, i.e., a plurality of floating gate electrodes 120b may be formed in both of the first and second directions, respectively. In some embodiments, the floating gate electrodes 120b may include polysilicon doped with n-type impurities such as arsenic or phosphorus.

The dielectric layer patterns 160a may be formed on the floating gate electrodes 120b and the isolation structures in the first direction, and each of the dielectric layer patterns 160a may extend in the second direction. The first air gap 146 may be formed between the isolation structure and the dielectric layer pattern 160a. The dielectric layer patterns 160a may include silicon oxide or silicon nitride. In some embodiments, each dielectric layer pattern 160a may include a multi-layered structure having a silicon oxide layer pattern 162a, a silicon nitride layer pattern 164a, and a silicon oxide layer pattern 166a. Some embodiments provide that each dielectric layer pattern 160a may include a metal oxide having a relatively high dielectric constant, thereby to increase capacitance and improve leakage current characteristics. Examples of the metal oxide having a relatively high dielectric constant may include hafnium oxide, titanium oxide, tantalum oxide, zirconium oxide, and/or aluminum oxide, among others. These may be used alone or in a combination thereof.

The control gate electrodes 170a may be formed on the dielectric layer patterns 160a. Thus, a plurality of control gate electrodes 170a may be formed in the first direction, and each of the control gate electrodes 170a may extend in the second direction. Some embodiments provide that the control gate electrodes 170a may serve as word lines. The control gate electrodes 170a may include a metal or polysilicon doped with n-type impurities.

Each isolation structure may include a liner 140a and a first filling layer 142.

The liner 140a may be formed on an inner wall of the trench 130 and a sidewall of a lower portion of the gate structure 200. In some embodiments, the liner 140a may have a top surface higher than that of the tunnel insulation layer pattern 110b. Thus, the liner 140a may cover a portion of the substrate 100 exposed by the trench 130, a sidewall of the tunnel insulation layer pattern 110b and a sidewall of a lower portion of the floating gate electrode 120b. Some embodiments provide that the liner 140a may include an oxide.

The first filling layer 142 may be formed on a portion of the liner 140a. Thus, the first filling layer also may extend in the first direction, and a plurality of first filling layers 142 may be formed in the second direction. In some embodiments, the first filling layer 142 may not completely fill the trench 130, and a top surface of the first filling layer 142 may be lower than a bottom surface of the tunnel insulation layer pattern 110b. The first filling layer 142 may include silicon oxide such as boro phospho silicate glass (BPSG), phospho silicate glass (PSG), undoped silicate glass (USG), spin on glass (SOG), flowable oxide (FOX), tetraethylorthosilicate (TEOS), plasma enhanced-TEOS (PE-TEOS), and/or high-density plasma-chemical vapor deposition (HDP-CVD) oxide, among others.

The first air gap 146 formed between the liner 140a, the first filling layer 142, the dielectric layer pattern 160a, the second insulation layer pattern 220, and the spacer 190 may extend in the first direction, and a plurality of first air gaps 146 may be formed in the second direction. The top surface of the first filling layer 142 may be lower than the bottom surface of the tunnel insulation layer pattern 110b, and thus a bottom surface of the first air gap 146 may be lower than a bottom surface of the gate structures 200.

As the first air gap 146 is formed between the active regions of the substrate 100, a channel coupling between the active regions may be reduced to improve programming characteristics of the non-volatile memory device.

The second insulation layer pattern 220 may be formed between the spacers 190 on a portion of sidewalls of the gate structures 200. The second insulation layer pattern 220 may extend in the second direction, and a plurality of second insulation layer patterns 220 may be formed in the first direction. In some embodiments, the second insulation layer pattern 220 may include silicon oxide such as a plasma enhanced oxide (PEOX) or a medium temperature oxide (MTO), among others.

The second air gap 222 may extend in the second direction. As the second air gap 222 is formed between the gate structures 200, a channel coupling between the word lines may be reduced to improve programming characteristics of the non-volatile memory device.

The spacers 190 may be formed on sidewalls of the dielectric layer pattern 160a and the control gate electrode 170a. The spacers 190 may extend in the second direction.

As described above, a parasitic capacitance and the channel coupling may be reduced by the first air gap 146 between the active regions and the second air gap 222 between the word lines, and thus the non-volatile memory device may have desired programming characteristics.

FIGS. 4 to 8 are cross-sectional views illustrating methods of manufacturing the non-volatile memory device in FIGS. 1 to 3 in accordance with some embodiments, and FIGS. 9 to 11 are perspective views illustrating methods of manufacturing the non-volatile memory device in FIGS. 1 to 3 in accordance with some embodiments.

Referring to FIG. 4, a tunnel insulation layer 110, a floating gate electrode layer 120, and a first mask 122 may be formed, sequentially, on a substrate 100.

The substrate 100 may include a semiconductor substrate such as a silicon substrate, a germanium substrate and a silicon-germanium substrate, a silicon-on-insulator (SOI) substrate, and/or a germanium-on-insulator (GOI) substrate, among others.

The tunnel insulation layer 110 may be formed using silicon oxide, silicon nitride, and/or silicon oxide doped with impurities. In some embodiments, tunnel insulation layer 110 may be formed by thermally oxidizing a top surface of the substrate 100.

The floating gate electrode layer 120 may be formed using polysilicon doped with impurities or a metal having a high work function such as tungsten, titanium, cobalt, and/or nickel, among others. In some embodiments, the floating gate electrode layer 120 may be formed by depositing a polysilicon layer through a low pressure chemical vapor deposition (LPCVD) process and doping n-type impurities into the polysilicon layer. In some embodiments, the floating gate electrode layer 120 may be formed to have a thickness equal to or more than about 1000 Å (Angstroms).

The first mask 122 may be a photoresist pattern or a hard mask. In some embodiments, the first mask 122 may have a linear shape extending in a first direction.

Referring to FIG. 5, the floating gate electrode layer 120 and the tunnel insulation layer 110 and an upper portion of the substrate 100 may be sequentially etched using the first mask 122 as an etching mask.

Thus, a preliminary tunnel insulation layer pattern 110a and a preliminary floating gate electrode 120a may be sequentially stacked on the substrate 100 and a trench 130 may be formed on the substrate 100. Each of the preliminary floating gate electrode 120a and the preliminary tunnel insulation layer pattern 110a may be formed to have a linear shape extending in the first direction, and a plurality of preliminary floating gate electrodes 120a and a plurality of preliminary tunnel insulation layer patterns 110a may be formed in a second direction that is substantially perpendicular to the first direction. The trench 130 may extend in the first direction, and a plurality of trenches 130 spaced apart from each other may be formed in the second direction.

A structure including the preliminary tunnel insulation layer pattern 110a, the preliminary floating gate electrode 120a and the first mask 122 may be defined as a preliminary floating gate structure, and a space between the preliminary floating gate structures may be defined as a first gap 135. A portion of the substrate 100 on which the trench 130 is formed may be defined as a field region, and a portion of the substrate 100 on which the trench 130 is not formed may be defined as an active region.

Referring to FIG. 6, a liner layer 140 may be formed on inner walls of the trench 130 and the first gap 135, and first and second filling layers 142 and 144 filling remaining portions of the trench 130 and the first gap 135 may be sequentially formed on the liner layer 140. The first and second filling layers 142 and 144 and the liner 140 may define a first insulation layer structure 150.

In some embodiments, the liner layer 140 may be formed using an oxide. Widths of the trench 130 and the first gap 135 may be reduced by the liner layer 140.

In some embodiments, the first filling layer 142 may be formed to have a top surface lower than a bottom surface of the preliminary tunnel insulation layer pattern 110a. The first filling layer 142 may be formed by a chemical vapor deposition (CVD) process, a plasma enhanced chemical vapor deposition (PECVD) process, a high-density plasma enhanced chemical vapor deposition (HDP-CVD) process and/or an atomic layer deposition (ALD) process, among others. The first filling layer 142 may be formed using silicon oxide such as boro phospho silicate glass (BPSG), phospho silicate glass (PSG), undoped silicate glass (USG), spin on glass (SOG), flowable oxide (FOX), tetraethylorthosilicate (TEOS), plasma enhanced-TEOS (PE-TEOS), and/or high-density plasma-chemical vapor deposition (HDP-CVD) oxide, among others.

In some embodiments, the second filling layer 144 may have a top surface substantially the same height as that of the first mask 122. The second filling layer 144 may be formed by a CVD process, a PECVD process, a HDP-CVD process or an ALD process. The second filling layer 144 may be formed using a material having a wet etch selectivity with respect to silicon oxide such as spin-on-hardmask(SOH), spin-on-glass(SOG), anti-carbon-layer(ACL), and/or silicon germanium(SiGe), among others.

Referring to FIG. 7, an upper portion of the first insulation layer structure 150 may be removed to form a first insulation layer structure pattern 150a, and thus an upper portion of the preliminary floating gate structure may be exposed.

Particularly, upper portions of the liner layer 140 and the second filling layer 144 may be removed to form the first insulation layer structure pattern 150a, and thus the first insulation layer structure pattern 150a may be formed to include a liner 140a, the first filling layer 142, and a second filling layer pattern 144a filling the trench 130 and a portion of the first gap 135. In some embodiments, the first insulation layer structure pattern 150a may be formed to have a top surface higher than that of the preliminary tunnel insulation layer pattern 110a. In some embodiments, the first insulation layer structure pattern 150a may be formed by an etch-back process.

The first mask 122 may be removed.

Referring to FIGS. 8 and 9, a dielectric layer 160 may be formed on the exposed preliminary floating gate structure and the top surface of the first insulation layer structure pattern 150a. A control gate electrode layer 170 filling a remaining portion of the first gap 135 may be formed on the dielectric layer 160.

The dielectric layer 160 may be formed using silicon oxide or silicon nitride. In some embodiments, the dielectric layer 160 may be formed using a multi-layered structure including a silicon oxide layer 162, a silicon nitride layer 164, and a silicon oxide layer 166. Some embodiments provide that the dielectric layer 160 may be formed using a metal oxide having a relatively high dielectric constant, which may increase capacitance and improve leakage current characteristics. Examples of the metal oxide having a relatively high dielectric constant may include hafnium oxide, titanium oxide, tantalum oxide, zirconium oxide, and/or aluminum oxide, among others.

The control gate electrode layer 170 may be formed using polysilicon doped with impurities, a metal, a metal nitride, and/or a metal silicide, among others. In some embodiments, the control gate electrode layer 170 may be formed using polysilicon doped with n-type impurities.

Referring to FIG. 10, a second mask (not illustrated) having a linear shape extending in the second direction may be formed on the control gate electrode layer 170. The control gate electrode layer 170, the dielectric layer 160, the preliminary floating gate electrode 120a, and the preliminary tunnel insulation layer pattern 110a may be etched using the second mask as an etching mask. Thus, a plurality of gate structures, each of which may include a tunnel insulation layer pattern 110b, a floating gate electrode 120b, a dielectric layer pattern 160a and a control gate electrode 170a sequentially stacked on the substrate 100, may be formed in the first direction, and a second gap 180 may be formed between the gate structures 200.

In some embodiments, the tunnel insulation layer patterns 110b and the floating gate electrodes 120b may be formed to have an island shape in the active region on the substrate 100. Ones of the dielectric layer patterns 160a and the control gate electrodes 170a may be formed to extend in the second direction. Thus, the control gate electrodes 170a may serve as word lines.

Referring to FIG. 11, spacers 190 may be formed on sidewalls of the gate structures 200.

In some embodiments, the spacers 190 may be formed using silicon oxide or silicon nitride. While performing an etching process, damage to the tunnel insulation layer patterns 110b and the dielectric layer patterns 160a included in the gate structures 200 may be reduced or prevented by the spacers 190.

Referring to FIG. 12, the second filling layer pattern 144a may be removed.

In some embodiments, the second filling layer pattern 144a may be removed using a wet etching solution having a relatively high etch selectivity between the first filling layer 142 and the second filling layer pattern 144a. Thus, not only the second filling layer pattern 144a exposed by the second gap 180 but also the second filling layer pattern 144a under the dielectric layer pattern 160a and the control gate electrode 170a may be removed, and a third gap 146 may be formed to extend in the first direction.

Referring now to FIGS. 1 to 3, a second insulation layer pattern 220 partially filling the second gap 180 may be formed between the gate structures 200.

Particularly, a process having a relatively low step coverage may be performed using silicon oxide such as a plasma enhanced oxide (PEOX) or a medium temperature oxide (MTO) so that a second insulation layer partially filling the second gap 180 may be formed on and between the gate structures 200. Thus, a second air gap 222 may be formed in the second insulation layer. In some embodiments, the second air gap 222 may be formed to extend in the second direction. An upper portion of the second insulation layer on the gate structures 200 may be removed to form the second insulation layer pattern 220.

In some embodiments, the second insulation layer pattern 220 may not be formed in the third gap 146. Hereinafter, the third gap 146 may be referred to as a first air gap 146 and, as described above, the first air gap 146 may extend in the first direction. As described above, the first air gap 146 may be formed to have a bottom surface lower than those of the gate structures 200. The first air gap 146 may be formed to have a top surface higher than a bottom surface of the floating gate electrode 120b.

The liner 140a and the first filling layer 142 may be formed between the active regions to form an isolation structure. The first air gap 146 may be located between the dielectric layer pattern 160a and the isolation structure.

Wirings such as a common source line (not illustrated), a bit line (not illustrated), etc. may be formed to complete the non-volatile memory device.

FIG. 13 is a perspective view illustrating a non-volatile memory device in accordance with some embodiments, and FIG. 14 is a plan view illustrating the non-volatile memory device in FIG. 13. The non-volatile memory device may be substantially the same as or similar to a non-volatile memory device of FIG. 1, except for shapes of a second insulation layer pattern and a first air gap. Thus, like reference numerals refer to like elements, and detailed descriptions thereabout may be omitted here.

Referring to FIGS. 13 and 14, a second insulation layer pattern 225 may be formed not only between spacers 190 but also on a top surface of a first filling layer 142, sidewalls of liner 140a, and a bottom surface of a dielectric layer pattern 160a, and thus the second insulation layer pattern 225 may include not only a second air gap 222 but also a first air gap 152 therein. A portion of the second insulation layer pattern 225 adjacent the liner 140a, the first filling layer 142, and the first air gap 152 may be included in an isolation structure.

The non-volatile memory device may be fabricated by methods substantially the same as or similar to methods illustrated with reference to FIGS. 4 to 11.

That is, after performing processes substantially the same as or similar to processes illustrated with reference to FIGS. 4 to 11, a second insulation layer may be formed, and an upper portion of the second insulation layer may be removed to form a second insulation layer pattern 225. The second insulation layer may be formed on an inner wall of a third gap 146, and thus the second insulation layer pattern 225 including first and second air gaps 152 and 222 therein may be formed.

FIG. 15 is a perspective view illustrating a non-volatile memory device in accordance with some embodiments. The non-volatile memory device may be substantially the same as or similar to a non-volatile memory device of FIG. 1, except for shapes of a second insulation layer pattern and a second air gap. Thus, like reference numerals refer to like elements and detailed descriptions thereabout may be omitted here.

Referring to FIG. 15, a second air gap 224 may be in fluid communication with a first air gap 146 to form a first air gap structure 230. Thus, the second air gap 224 may not be completely surrounded by a second insulation layer pattern 227. That is, the second air gap 224 may be a recess beneath a lower portion of the second insulation layer pattern 227.

The non-volatile memory device may be fabricated by methods substantially the same as or similar to methods illustrated with reference to FIGS. 4 to 11.

That is, after performing processes substantially the same as or similar to processes illustrated with reference to FIGS. 4 to 11, a second insulation layer may be formed, and an upper portion of the second insulation layer may be removed to form a second insulation layer pattern 227. The second insulation layer may be formed so that a second air gap 224 may be in fluid communication with a first air gap 146, and thus the non-volatile memory device may be fabricated.

FIG. 16 a perspective view illustrating a non-volatile memory device in accordance with some embodiments. The non-volatile memory device may be substantially the same as or similar to a non-volatile memory device of FIG. 1, except for shapes of a second insulation layer pattern and a second air gap. Thus, like reference numerals refer to like elements and detailed descriptions thereabout may be omitted here.

Referring to FIG. 16, a second insulation layer pattern 229 may be formed not only between spacers 190 but also on a top surface of a first filling layer 142, sidewalls of a liner 140a, and a bottom surface of a dielectric layer pattern 160a, and thus the second insulation layer pattern 229 may include a first air gap 152 therein. A portion of the second insulation layer pattern 229 adjacent the liner 140a, the first filling layer 142, and the first air gap 152 may be included in an isolation structure. A second air gap 224 may be in fluid communication with the first air gap 152, and thus a second air gap structure 235 may be formed.

The non-volatile memory device may be fabricated by methods substantially same as or similar to methods illustrated with reference to FIGS. 4 to 11.

That is, after performing processes substantially the same as or similar to processes illustrated with reference to FIGS. 4 to 11, a second insulation layer may be formed, and an upper portion of the second insulation layer may be removed to form a second insulation layer pattern 229. The second insulation layer may be formed on an inner wall of a third gap 146, and thus the second insulation layer pattern 229 including a first air gaps 152 therein may be formed. The second insulation layer may be formed so that a second air gap 224 may be in fluid communication with a first air gap 152, and thus the non-volatile memory device may be fabricated.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A non-volatile memory device comprising:
a substrate including a plurality of active regions and a plurality of field regions extending in a first direction and alternately and repeatedly formed in a second direction that is substantially perpendicular to the first direction;
a plurality of gate structures on the substrate and spaced apart from each other in the first direction, each of the gate structures extending in the second direction;
an insulation layer pattern between adjacent ones of the plurality of gate structures, the insulation layer pattern having a second air gap therein; and
an isolation structure on the substrate in ones of the plurality of field regions, the isolation structure extending in the first direction and having a first air gap between the gate structures, the insulation layer pattern, and the isolation structure.

2. The non-volatile memory device according to claim 1, wherein ones of the plurality of active regions of the substrate protrude from ones of the plurality of field regions of the substrate.

3. The non-volatile memory device according to claim 2, wherein the isolation structure comprises a liner and a filling layer that are sequentially stacked on the substrate in ones of the plurality of field regions.

4. The non-volatile memory device according to claim 3, wherein the liner extends along sidewalls of the protruded active regions and has a cup-shape that includes a central portion that is substantially empty, and
wherein the filling layer is configured to partially fill the central portion of the liner.

5. The non-volatile memory device according to claim 4, wherein the first air gap is defined by a top surface of the filling layer, a sidewall of the liner, a bottom surface of a respective one of the plurality of gate structures, and a bottom surface of the insulation layer pattern.

6. The non-volatile memory device according to claim 1, wherein ones of the plurality of gate structures include a tunnel insulation layer pattern, a floating gate electrode, a dielectric layer pattern, and a control gate electrode that are sequentially stacked on the substrate.

7. The non-volatile memory device according to claim 6, wherein the tunnel insulation layer pattern and the floating gate electrode are formed in the active regions, and
wherein the dielectric layer pattern and the control gate electrode extend in the second direction in the plurality of active regions and the plurality of field regions.

8. The non-volatile memory device according to claim 7, wherein the first air gap is defined by the isolation structure, a bottom surface of the dielectric layer pattern and a bottom surface of the insulation layer pattern.

9. The non-volatile memory device according to claim 7, wherein the first air gap has a bottom surface that is lower than that of the tunnel insulation layer pattern and a top surface that is higher than a bottom surface of the floating gate electrode.

10. The non-volatile memory device according to claim 1, wherein the first air gap and second air gap are in fluid communication with each other.

11. The non-volatile memory device according to claim 1, wherein the insulation layer pattern is also formed on a top surface of the isolation structure and on bottom surfaces of ones of the plurality of gate structures, so that the first air gap is formed in the insulation layer pattern.

12. The non-volatile memory device according to claim 11, wherein the first air gap and the second air gap are in fluid communication with each other.

13. The non-volatile memory device according to claim 1, further comprising spacers on sidewalls of ones of the plurality of gate structures, wherein the insulation layer pattern is formed between the spacers.

14. The non-volatile memory device according to claim 1, wherein the first air gap extends in the first direction, and the second air gap extends in the second direction.

15-19. (canceled)
